(19) United States
(12) Patent Application Publication
(10) Pub. No.: US 2009/0072902 A1
(43) Pub. Date: Mar. 19, 2009

(54) LOW DISTORTION CLASS-D AMPLIFIER

(75) Inventor: Stephen Michael Cox, Southern Australia (AU)

Correspondence Address: BROOKS KUSHMAN P.C., 1000 TOWN CENTER, TWENTY-SECOND FLOOR, SOUTHFIELD, MI, 48075, US

(73) Assignee: EXTRAORDINARY TECHNOLOGY PTY LTD, Torrensville, S.A. (AU)

(21) Appl. No.: 11/577,676

(22) PCT Filed: Oct. 26, 2005
(86) PCT No.: PCT/AU05/01657

§ 371 Date: Apr. 20, 2007

(30) Foreign Application Priority Data
Oct. 27, 2004 (AU) 2004906162

(51) Int. Cl. H03F 3/217

(52) U.S. Cl. 330/251

(57) ABSTRACT

An electronic class-D amplifier having an amplifier input to which an amplifier input signal may be applied, an amplifier output which may produce an amplifier output signal, an output switching stage, a pulse width modulator which includes an oscillator, wherein a first output of the oscillator produces a carrier reference signal, at least one servo-loop amplifier which includes an integrating feed forward transfer function, wherein the amplifier input is connected to an input of the servo-loop amplifier, a sample and hold element which includes a sample input and a control input, such that the sample and hold element samples a signal at the sample input when a sample command signal is applied to the control input, and the sample and hold element holds the value of the last sampled value of the signal at the sample input when the hold command signal is applied to the control input, and this said held value is applied to an output of the sample and hold element, the amplifier input is also connected to the sample input of the sample and hold element, an output of the sample and hold element is connected to a first input of an adder, and an output of the servo-loop amplifier is connected to a second input of the adder, an output of the adder is connected to a modulation input of the pulse width modulator, a second output of the oscillator is connected to the control input of the sample and hold element, an output of the pulse width modulator is connected to an input of the output switching stage, and an output of the output switching stage is connected to the amplifier output, wherein a negative feedback path connects an output of the output switching stage to an input of the servo-loop amplifier.

### TECHNICAL FIELD

This invention relates to a class-D switching amplifier and has particular application to class-D analogue power amplifiers, particularly audio frequency amplifiers.

### BACKGROUND ART

The following descriptions are provided to assist the reader to understand how the current inventor has proceeded to analyse circuits of which he is aware to assist the reader to understand the relevance of the circuit invention. However these references are not intended and do not of themselves provide any admission by the applicant that they are published as may be required for an assessment of novelty or obviousness or are common general knowledge according to the laws of and in any particular country in the world.

Several models of commercial switching amplifiers are known which include class-D amplifiers. Most utilise a system including a first order servo-loop amplifier whose output is connected to a modulation input of a pulse width modulator. An output of the pulse width modulator is connected to an input of an output switching stage. A negative feedback path connects an output of the output switching stage to an input of the servo-loop amplifier and an amplifier input is also connected to an input of the servo-loop amplifier. This system may be viewed conceptually as the output of the servo-loop amplifier, being an integral of an error signal, the error signal being proportional to the difference between the scaled output of the output switching stage and amplifier input signals. This integrated error signal is that which is fed to the said modulation input.

The pulse width modulator in some systems includes a triangular-wave oscillator which acts as a carrier reference signal, which is applied to an input of a comparator. In some systems which are less common, the carrier reference is a sawtooth waveform rather than a triangular-wave. An output of the servo-loop amplifier is also applied to an input of the comparator. The comparator and the triangular wave oscillator act as the said pulse width modulator, wherein an output of the comparator acts as the output of the pulse width modulator. The servo-loop amplifier most often has a forward transfer function which is an input current to output voltage integrator.

This system uses negative feedback to reduce distortion, that is, improve accuracy. However, this system is known intrinsically to produce distortion or in other words non-linearity between the amplifier input and amplifier output forward transfer ratio at frequency components well below the carrier reference signal. That is, the system produces distortion even for near perfect electronic components, or in other words, mathematically for idealised components.

In addition, electronic imperfections which are significant, for example in practical power output switching stages, produce further errors.

Details of a system utilising these basic functions is given in Motorola application note AN1042.

A simpler class-D amplifier with no negative feedback or servo-loop amplifier and direct input signal modulation of the pulse width modulator is utilised by a Zetex integrated circuit ZXCD1000. Assuming all components are ideal in such a system concept, this idealised system is known to produce no distortion in contrast to the servo-loop system described above. However, this direct modulation system in practice is known to have several problems compared to the servo-loop approach, namely:

The output noise is typically higher owing to no feedback.

The distortion resulting from practical electronic components is higher at low frequencies where negative feedback of the servo-loop system is of assistance.

The output signal of the direct modulation system is proportional to the output stage supply rails and is thus modulated by variations in these rails. Owing to negative feedback, this effect is reduced in the servo-loop system, particularly at lower frequencies which has advantage of more negative feedback.

Class-D amplifiers have been developed by Bang and Olufsen which this company calls its “ICEpower” products. The principles of this system are described in numerous Audio Engineering Society publications and U.S. Pat. No. 6,297,692. This discloses an analogue switching amplifier, in which the overall amplifier dominant pole is set by elements both in the forward servo-loop amplifier paths and also in the negative feedback paths.

An object of this invention is therefore to provide an amplifier improvement that assists in reducing distortion or at least provides the public with a useful alternative.

### SUMMARY OF INVENTION

In one form of this invention although this need not be the only or indeed the broadest of this there is provided an electronic class-D amplifier having

an amplifier input to which an amplifier input signal may be applied,
an amplifier output which may produce an amplifier output signal,
an output switching stage,
a pulse width modulator which includes an oscillator, wherein a first output of the oscillator produces a carrier reference signal,
at least one servo-loop amplifier which includes an integrating feed forward transfer function, wherein the amplifier input is connected to an input of the servo-loop amplifier, a sample and hold element which includes a sample input and a control input, such that the sample and hold element samples a signal at the sample input when a sample command signal is applied to the control input, and the sample and hold element holds the value of the last sampled value of the signal at the sample input when the hold command signal is applied to the control input, and this said held value is applied to an output of the sample and hold element,
the amplifier input is also connected to the sample input of the sample and hold element,
an output of the sample and hold element is connected to a first input of an adder,
and an output of the servo-loop amplifier is connected to a second input of the adder,
an output of the adder is connected to a modulation input of the pulse width modulator,
a second output of the oscillator is connected to the control input of the sample and hold element,
an output of the pulse width modulator is connected to an input of the output switching stage,
and an output of the output switching stage is connected to the amplifier output,
wherein a negative feedback path connects an output of the output switching stage to an input of the servo-loop amplifier.

In preference the invention is further characterised in that the pulse width modulator includes a comparator,

the output of the adder is connected to an input of the comparator,
and the first output of the oscillator is connected to an input of the comparator which may include the adder,
and an output of the comparator is an output of the pulse width modulator.

In preference the invention is further characterised in that the sample command occurs in time close to the time of peak signals of the carrier reference signal and the hold command occurs at all other times.

In preference the invention is further characterised to include at least one power supply which supplies power to the output switching stage adapted such that peak signals of the carrier reference signal track a potential difference between power supply rails which supply power to the output switching stage.

In preference the invention is further characterised in that a forward gain of the output switching stage, a forward transfer function of the servo-loop amplifier, a forward gain of the sample and hold element, and modulation forward gain of the oscillator, and carrier reference output signal's mean frequency, and gain of the negative feedback path, and the relationship between the timing of the sample command and hold command signals relative of peaks of the carrier reference signal,

are selected to improve linearity of a signal at the amplifier output relative to a signal applied to the amplifier input.

In preference the invention is further characterised in that the oscillator includes a wide-band amplifier with a unity-gain-bandwidth of at least greater than 100 MHz.

In preference the invention is further characterised in that the mean output carrier reference signal frequency, and peak signals from the output of the output switching stage and potential currents flowing within this stage, are consistent with class-D power audio amplification.

In a further form this invention can be said to reside in a method of amplification which includes the steps of introducing a signal to be amplified into an amplifier as above characterised.

The theory underlying this invention will be disclosed in a paper to be published in an applied maths journal, the details of which will be known when this provisional patent is filled as an application.

For a better understanding, further description will now be given, with reference to drawings in which:

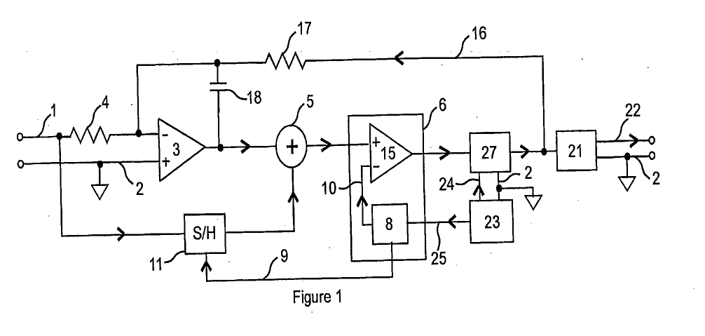

FIG. 1 is a functional block diagram of the invention.

In FIG. 1 an amplifier input 1 to which an amplifier input signal may be applied, feeds an input of a servo-loop amplifier which may be thought of as consisting of operational amplifier 3, resistors 4 and capacitor 18. Resistor 4 connects the input of the servo-loop amplifier to an inverting input of operational amplifier 3. The amplifier input and amplifier output include an amplifier earth reference 2, which is also connected to a output of the servo-loop amplifier The amplifier input is also connected to a sample input of a sample and hold element, such that the sample and hold element samples a signal at the sample input when a sample command signal is applied to the control input, and the sample and hold element holds the value of the last sampled value of the signal at the sample input when the hold command signal is applied to the control input, and this said held value is applied to an output of the sample and hold element. The output of the sample and hold element 11 is connected to a second input of the adder 5. The adder adds a signal at the first input to a signal at the second input to give a sum output at an output of the adder. An output of the adder is connected to a modulation input of a pulse width modulator 6. Shown here for example, the said modulation input is non-inverting input of a comparator 15. An output of the pulse width modulator, shown here for example as an output of comparator 15 is fed to an input of an output switching stage 27. Resistor 17 is connected between an output 16 of the output switching stage 27, and the inverting input of the servo-loop amplifier. This forms a negative feedback path. The output 16 of the output switching stage 27 is connected to a filter 21 which removes carrier reference related signals and harmonics. In most class-D amplifier products, this is usually a low-pass filter. The output of this filter feeds the amplifier output 22 which may produce an amplifier output signal. However, it is not essential to include this filter depending on application.

An oscillator 8 which produces a carrier reference signal at a first output 10 is connected to an inverting input of the comparator. Alternatively, the carrier reference signal may be connected to a third input of the adder 5, and the inverting input of the comparator 15 connected to the earth reference 2. This carrier reference signal usually is a triangular-wave signal in most analogue class-D amplifier products. Oscillator 8 produces at a second output relatively short duration sample command signal pulses close in time to the peaks of the carrier reference signal. These short duration sample command signal pulses are applied to a control input 9 of the sample and hold element 11. At all other times, a hold command signal is applied to control input 9.

The output switching stage is supplied by power supply 23 via power rail 24. A signal in proportion to the difference in potential between the power rail 24 and earth reference 2 is fed to an input 25 of the oscillator 8, such that the peak voltages of the carrier reference triangular-wave signal track this said difference in potential. This feature compensates for power supply voltage variation and modulation, which may occur from varying current being supplied to the amplifier or un-regulated power supplies for example. This feature is necessary for the distortion cancellation to be accurate.

Owing to the relatively high frequency of typical carrier reference signals (>=500 kHz), which no doubt will increase as electronic components improve in future years, it is beneficial for accuracy of the carrier signal and hence whole amplifier to utilise a wideband operational amplifier within the oscillator integrating elements owing to the relatively high gains of such devices at the carrier reference signal frequency and its harmonics. For example, a wideband amplifier with a unity-gain-bandwidth of more than 100 MHz is useful.

It is possible to produce an audio power amplifier using these techniques with similar performances to common well designed class-A, -B, or -AB analogue amplifiers.

Throughout this specification the purpose of the description has been to illustrate the invention and not to limit this.

Extraordinary Technologies Pty Ltd.

1. An electronic class-D amplifier having
an amplifier input to which an amplifier input signal may be applied,
an amplifier output which may produce an amplifier output signal,
an output switching stage,
a pulse width modulator which includes an oscillator, wherein a first output of the oscillator produces a carrier reference signal,
at least one servo-loop amplifier which includes an integrating feed forward transfer function, wherein the amplifier input is connected to an input of the servo-loop amplifier, a sample and hold element which includes a sample input and a control input, such that the sample and hold element samples a signal at the sample input when a sample command signal is applied to the control input, and the sample and hold element holds the value of the last sampled value of the signal at the sample input when the hold command signal is applied to the control input, and this said held value is applied to an output of the sample and hold element,
the amplifier input is also connected to the sample input of the sample and hold element,
an output of the sample and hold element is connected to a first input of an adder,
and an output of the servo-loop amplifier is connected to a second input of the adder,
an output of the adder is connected to a modulation input of the pulse width modulator,
a second output of the oscillator is connected to the control input of the sample and hold element,
an output of the pulse width modulator is connected to an input of the output switching stage,
and an output of the output switching stage is connected to the amplifier output,
wherein a negative feedback path connects an output of the output switching stage to an input of the servo-loop amplifier.

2. The amplifier of claim 1 wherein the pulse width modulator includes a comparator,
the output of the adder is connected to an input of the comparator,
and the first output of the oscillator is connected to an input of the comparator which may include the adder,
and an output of the comparator is an output of the pulse width modulator.

3. The amplifier of claim 1 wherein the sample command occurs in time close to the time of peak signals of the carrier reference signal and the hold command occurs at all other times.

4. The amplifier of claim 1 where there is at least one power supply which supplies power to the output switching stage adapted such that peak signals of the carrier reference signal track a potential difference between power supply rails which supply power to the output switching stage.

5. The amplifier of claim 1 where there is a forward gain of the output switching stage, a forward transfer function of the servo-loop amplifier, a forward gain of the sample and bold element, and modulation forward gain of the oscillator, and carrier reference output signal's mean frequency, and gain of the negative feedback path, and the relationship between the timing of the sample command and hold command signals relative of peaks of the carrier reference signal,
are selected to improve linearity of a signal at the amplifier output relative to a signal applied to the amplifier input.

6. The amplifier of claim 1 wherein the oscillator includes a wide-band amplifier with a unity-gain-bandwidth of at least greater than 100 MHz.

7. The amplifier of claim 1 wherein the mean output carrier reference signal frequency, and peak signals from the output of the output switching stage and potential currents flowing within this stage, are consistent with class-D power audio amplification.
